(19) United States
(12) Patent Application Publication
(10) Pub. No.: US 2011/0317390 A1
(43) Pub. Date: Dec. 29, 2011

(54) Electronics housing for an electronic device, and a device formed therewith

(75) Inventors: Thierry Moser, Sierentz (FR); Ole Koudal, Braden (CH); Nikolai Fink, Aesch (CH); Roland Unterseh, St. Louis (FR); Markus Beissert, Freiburg (DE); Frank Bonschab, Rummingen (DE); Gernot Engstler, Riehen (CH)

(73) Assignee: Endress + Hauser Flowtec AG, Reinach (CH)

(21) Appl. No.: 13/164,847

(22) Filed: Jun. 21, 2011

(30) Foreign Application Priority Data
Jun. 21, 2010 (DE) DE 102010030288.0
Jul. 5, 2010 (DE) DE102010030924.9

(51) Int. Cl. H05K 7/02; H05K 7/00

(52) U.S. Cl. 361/807; 361/679.01

(57) ABSTRACT

An electronics housing comprises a housing basic body having a cavity, especially a single cavity. The housing basic body includes a side wall laterally bordering the cavity, an open end and a rear wall bounding the cavity on an end lying opposite the open end and remote therefrom. Also included is a housing lid releasably connected to the housing basic body on the open end and sealing the housing basic body; and an intermediate floor. The intermediate floor, in the case of the electronics housing of the invention, forms: a gap extending between an inner surface of the side wall of the housing basic body and a lateral surface of the intermediate floor facing the inner surface; and two housing chambers in the cavity of the housing basic body separated from one another by the intermediate floor. A first housing chamber is arranged on a first side of the intermediate floor facing the housing lid and a second housing chamber is arranged on a second side of the intermediate floor facing away from the housing lid. The intermediate floor is inserted into, and releasably affixed to, the housing basic body.

The invention relates to an electronics housing for an electronic device, especially embodied as a measuring and/or switching device for industrial measuring and automation technology, as well as to an electronic device formed therewith.

Electrical measuring and/or switching devices installed near a process, known as field devices, such as e.g. Coriolis mass flow measuring devices, density measuring devices, magnetically inductive flow measuring devices, vortex flow measuring devices, ultrasound flow measuring devices, thermal mass flow measuring devices, pressure measuring devices, fill level measuring devices, temperature measuring devices, pH measuring devices etc., are applied in industrial process measurements technology, especially also in connection with the automation of chemical or manufacturing processes and/or the automated control of industrial plants; these devices serve to produce—in analog or digital form—measured values representing process variables as well as signals carrying these measured values. The process variables to be registered can be, depending on application, for example, mass flow, density, viscosity, fill level or a limit level, pressure or temperature, or the like, of a liquid, powdered, vaporous or gaseous medium, which is conveyed or held in a corresponding container such as e.g. a pipeline or a tank.

For registering the respective process variables, electronic devices of the aforementioned type have a corresponding physical to electrical or chemical to electrical measuring transducer. Such is most often applied in a wall of the container containing the medium or a wall of a line conveying the medium, for example, a pipeline, and serves to produce at least one electrical measurement signal corresponding to the process variable to be registered. For processing the measurement signal, the measuring transducer is further connected with a operating- and evaluating circuit provided in a measuring device internal device electronics of the field device for the further processing or evaluation of the at least one measurement signal, as well as also for generating corresponding measured value signals. Further examples for such measuring devices known to those skilled in the art, especially also their application and their details concerning operation, are, among other things, described in WO-A 03/048874, WO-A 02/45045, WO-A 02/103327, WO-A 02/086426, WO-A 01/02816, WO-A 00/48157, WO-A 00/36 379, WO-A 00/14 485, WO-A 95/16 897, WO-A 88/02 853, WO-A 88/02 476, U.S. Pat. No. 7,134,348, U.S. Pat. No. 7,133,727, U.S. Pat. No. 7,075,313, U.S. Pat. No. 7,073,396, U.S. Pat. No. 7,032,045, U.S. Pat. No. 6,854,055, U.S. Pat. No. 6,799,476, U.S. Pat. No. 6,776,053, U.S. Pat. No. 6,769,301, U.S. Pat. No. 6,662,120, U.S. Pat. No. 6,640,308, U.S. Pat. No. 6,577,989, U.S. Pat. No. 6,574,515, U.S. Pat. No. 6,556,447, U.S. Pat. No. 6,539,819, U.S. Pat. No. 6,535,161, U.S. Pat. No. 6,512,358, U.S. Pat. No. 6,487,507, U.S. Pat. No. 6,480,131, U.S. Pat. No. 6,476,522, U.S. Pat. No. 6,397,683, U.S. Pat. No. 6,366,436, U.S. Pat. No. 6,352,000, U.S. Pat. No. 6,311,136, U.S. Pat. No. 6,295,874, U.S. Pat. No. 6,285,094, U.S. Pat. No. 6,269,701, U.S. Pat. No. 6,236,322, U.S. Pat. No. 6,140,940, U.S. Pat. No. 6,051,783, U.S. Pat. No. 6,014,100, U.S. Pat. No. 6,006,609, U.S. Pat. No. 5,959,372, U.S. Pat. No. 5,796,011, U.S. Pat. No. 5,742,225, U.S. Pat. No. 5,742,225, U.S. Pat. No. 5,706,007, U.S. Pat. No. 5,687,100, U.S. Pat. No. 5,672,975, U.S. Pat. No. 5,604,685, U.S. Pat. No. 5,535,243, U.S. Pat. No. 5,469,748, U.S. Pat. No. 5,416,723, U.S. Pat. No. 5,363,341, U.S. Pat. No. 5,359,881, U.S. Pat. No. 5,231,884, U.S. Pat. No. 5,207,101, U.S. Pat. No. 5,131,279, U.S. Pat. No. 5,068,592, U.S. Pat. No. 5,065,152, U.S. Pat. No. 5,052,230, U.S. Pat. No. 4,926,340, U.S. Pat. No. 4,850,213, U.S. Pat. No. 4,768,384, U.S. Pat. No. 4,716,770, U.S. Pat. No. 4,656,353, U.S. Pat. No. 4,617,607, U.S. Pat. No. 4,594,584, U.S. Pat. No. 4,574,328, U.S. Pat. No. 4,524,610, U.S. Pat. No. 4,468,971, U.S. Pat. No. 4,317,116, U.S. Pat. No. 4,308,754, U.S. Pat. No. 3,878,725, US-A 20090277278, US-A 2007/0217091, US-A 2006/0179956, US-A 2006/0161359, US-A 2006/0120054, US-A 2006/0112774, US-A 2006/0096390, US-A 2005/0139015, US-A 2004/0183550, US-A 2004/0117675, EP-A 1 669 726, EP-A 1 158 289, EP-A 1 147 463, EP-A 1 058 093, EP-A 984 248, EP-A 591 926, EP-A 525 920, DE-A 102005 032 808, DE 100 41 166, DE-A 44 12 388, DE-A 39 34 007 or DE-A 37 11 754.

In a great number of field devices of the type being discussed, the measuring transducer for producing the measurement signal during operation is additionally operated by a driver signal generated at least at times by the operating and evaluating circuit, so that the transducer acts on the medium in a manner suited for measuring at least indirectly or, however also directly via a probe practically directly contacting the medium, in order to bring about reactions corresponding to a measured variable to be registered. The driver signal can be correspondingly controlled, in such case, as regards an electrical current level, a voltage level and/or a frequency, for example. Examples of such active measuring transducers thus correspondingly converting an electrical driver signal in the medium include flow measuring transducers especially serving to measure media flowing at least at times, e.g. especially flow measuring transducers having at least one coil driven by the driver signal to produce a magnetic field or at least one ultrasonic transmitter driven by the driver signal, or, however, also fill level and/or limit level transducers serving to measure and/or monitor fill levels in a container, such as e.g. those with freely radiating microwave antenna, a Goubau line or a vibrating immersion element.

In electronic devices of the type being discussed, the particular device electronics can usually be electrically connected via corresponding electrical lines to a superordinated electronic data processing system most often arranged spatially removed from the respective device and most often also spatially distributed, to which the measured values produced by the respective device are forwarded by means of a measured value signal correspondingly carrying these measured values in real time. Additionally, such devices during operation are usually connected with one another and/or with corresponding electronic process controls by means of a data transmission network provided within the superordinated data processing system; examples of electronic process controls are programmable logic controllers installed onsite or process control computers installed in a remote control room; the coded measured values produced in given cases by means of the device and digitized in a suitable manner are correspondingly forwarded to the corresponding electronic process controls. By means of such process control computers, the transmitted measured values can be further processed and shown as corresponding measurement results, e.g. on monitors, and/or be converted to control signals for other field devices embodied as actuating devices, such as e.g. magnetic valves, electric motors, etc. Since modern measuring arrangements formed by devices of the type being discussed are most often monitored and, in given cases, controlled and/or configured directly by such control computers, operating data intended for each field device is equally dispatched in a corresponding manner via the aforementioned data transmission networks, most often hybrid as regards the transmission physics and/or the transmission logic. Accordingly, the data processing system usually also serves to condition the measured value signal in given cases delivered by the field device, in accordance with the requirements of downstream data transmission networks; for example, to digitize the measured value signal and, in given cases, convert it to a corresponding telegram, and/or evaluate it onsite. For such a purpose, evaluating circuits electrically coupled via the respective connecting lines are provided in such data processing systems; the evaluating circuits pre and/or post process as well as, in case it is required, suitably convert the measured values received from the respective electronic device embodied, for instance, as a measuring and/or switching device. In such industrial data processing systems, field busses, such as e.g. FOUNDATION FIELDBUS, RACKBUS-RS 485, PROFIBUS etc. or also, for example, networks based on the ETHERNET standard as well as the corresponding, most often comprehensively standardized transmission protocols serve for data transmission at least sectionally, especially serially. In addition to the evaluating circuits required for processing and converting the measured values delivered by each connected field device, such superordinated data processing systems most often also have electrical supply circuits serving to supply electrical energy to the connected measuring and/or switching devices; the electrical supply circuits provide a corresponding supply voltage, fed directly from the connected fieldbus in given cases to the particular device electronics and drive electrical currents flowing through the connected electrical lines as well as through the respective device electronics. In such a case, a supply circuit can be associated with exactly one field device, for example, and be accommodated in an electronics housing formed e.g. as a hatrail module, shared together with the evaluating circuit associated with the respective field device—united to form a corresponding fieldbus adapter, for example.

In the case of devices of the type being discussed, consequently field devices from industrial measuring and automation technology, the particular device electronics is most often accommodated in a comparatively robust, for instance, impact, pressure, explosion and/or weather proof, electronics housing. As provided in e.g. in U.S. Pat. No. 6,397,683 or WO-A 00/36379, this can be arranged remotely from the field device and only connected to this via a flexible line; however, it can also be arranged directly on the measuring transducer or on a measuring transducer housing separate from the measuring transducer. In given cases, the electronics housing, as shown, for example, in EP-A 984 248, U.S. Pat. No. 4,594,584, U.S. Pat. No. 4,716,770 or U.S. Pat. No. 6,352,000, can then also serve to accommodate some mechanical components of the measuring transducer, such as e.g. membrane, rod, sleeve or tubular deformation or vibrating elements operationally deforming under mechanical action; also compare the previously mentioned U.S. Pat. No. 6,352,000 or U.S. Pat. No. 6,051,783 for this.

Examples of such electronics housings of the type being discussed suitable for electronic devices are described, among other things, in the previously mentioned U.S. Pat. No. 6,366,436 or also in DE-A 101 26 654, DE-A 10 2008 042972, U.S. Pat. No. 6,556,447, WO-A 97/12206 or WO-A 98/14763. In accordance therewith, such electronics housings comprise a housing basic body, most often pot shaped, having one or a number of cavities, with a side wall, most often sectionally circularly cylindrical, bordering its cavity laterally, with an open end and with a rear wall, for example, a flat or outwardly convex, rear wall, bounding the cavity on an end lying opposite the open end and remote therefrom, in given cases also a releasable, rear wall, as well as a housing lid, which is releasably connected to the housing basic body on its open end, for example, by means of a screw connection, and which seals the open end. The housing lid, most often also having an integrated viewing window, is usually screwed to the housing basic body, for example, in the manner of a screwed closure.

Industrial strength electrical devices or also electronic devices, therefore each particular electronics housing and each device electronics accommodated therein, must, as is known, satisfy very high protection requirements, especially in regards to shielding the electrical components placed therein against outside environmental influences, in regards to protecting against possible touching by voltage carrying components and/or in regards to suppressing electrical ignition sparks in the case of malfunction. This especially includes the requirement, as set forth, for example, in DE-A 100 41 166, that an electrical current that could flow to ground or earth via an electronics housing in the case of ground fault for example, is not permitted to exceed a maximum allowable highest value. This allowable highest value is, for example, 10 mA in the case of a connection of the electrical device to 250 V. If these requirements are fulfilled, then the device corresponds to at least the requirements of protection class 11, that is, it is an electrical device with protective isolation. For implementing these requirements, it is accordingly required that the housing of the electrical device be sufficiently insulated from all voltage carrying parts of the device. Such insulation is especially necessary when it is a housing comprising an electrically conductive material, a metal, for example. Moreover, electronics housings, including the device electronics placed therein, are to be protected in sufficient measure against penetration of moisture or impurities, especially dust, as well as from external contact. The degree of protection corresponding to the given application and environmental conditions to be provided by the respective electronics housing against penetration, for instance, by contact, contaminating particles, or water, is determinable, for example, from the protection types defined by German standards DIN EN 60529, or DIN 40 050, e.g. “protected from dust, or from water spray on all sides (IP54)” or “dust tight, or continuous immersion (IP68)”, and, respectively, protection classes or according to the industrial standard NEMA 250.

Electrical devices, consequently also field devices, which are also to be operated in explosion endangered areas, must also satisfy moreover very high safety requirements in regard to explosion protection. In such a case, it is especially a matter of safely preventing the formation of sparks or at least assuring that sparks possibly occurring in the interior of a closed space have no effects on the environment in order to safely avoid the potential possible triggering of an explosion. For example, for explosion protection as executed in U.S. Pat. No. 6,366,436, U.S. Pat. No. 6,556,447 or US-A 2007/0217091 as well as in the previously mentioned EP-A 1 669 726, different ignition protection types are distinguished in connection with explosion protection; each ignition protection type is correspondingly manifested in standards and norms relevant to electrical operating means for explosion endangered areas; Examples of such include the European standards EN 60079-xx, the US-American standards FM36xx, the Canadian standard C22.2, the international standard IEC 60079-18 or the standard DIN EN 50 014 ff. Thus, e.g. according to the European standard EN 60079-11:2007, explosion protection is given when devices are embodied according to the ignition protection type defined therein or also the protection class with the name “Intrinsic Safety” (Ex-i). In this protection class, the values for each electrical variable, electrical current, voltage and power, have to lie below a predetermined limit value in a device at all times. The three limit values are selected so that, in the case of a malfunction, e.g. a short circuit, the maximum occurring heat is not sufficient to produce an ignition spark. The electrical current is held below the predetermined limit value, e.g. by resistors, the voltage, e.g. by Zener diodes and the power by a corresponding combination of flow and voltage limiting components. In European standard EN 60079-7:2007, another protection class with the name “Increased Safety” (Ex-e) is given. In the case of devices, which are embodied according to this protection class, the ignition, or explosion protection is achieved by having the spatial distances between two different electrical potentials be so large that a formation of a spark cannot occur due to the distance, even in the case of malfunction. This can, however, under certain circumstances, lead to the circuit arrangements having to have very large dimensions in order to satisfy these requirements. Additionally the ignition protection type “Pressure Resistant Encapsulation’” (Ex-d) is specified as another protection class in European standard EN 60079-1:2007. Electrical devices embodied according to this protection class must have a pressure resistant housing, through which it is assured, that an explosion occurring in the interior of the housing cannot be transmitted into the external space. Pressure resistant housings are embodied with comparatively thick walls, in order to have a sufficient mechanical strength. Another standard, namely EN 60079-18:2004, relates to the protection class “Encapsulation by Potting” (Ex-m). In such a case, involved is an ignition protection type, in which the components and/or assemblies of the electrical device, which could potentially ignite an explosive atmosphere by sparks or through warming, are most often encapsulated in an elastomeric and/or foam embedding compound comprising a synthetic material, so that contact with the explosion endangered atmosphere can be largely excluded and therefore an ignition can be suppressed. In the USA, Canada, Japan and other countries, standards, for instance, FM3600, FM3610, or C22.2 No. 157 etc. are comparable with the aforementioned European standards

In the case of devices of the type being discussed, additionally, it is quite usual to construct the device electronics modularly, namely comprising a plurality of electrical/electronic assemblies/modules, and these assemblies are arranged in housing compartments separated from one another; the housing compartments are formed within the housing basic body, also in given cases, each satisfies the requirements of another of the aforementioned protection classes. For the purpose of electrical connection of assemblies separated spatially from one another in this manner as shown, among other things, in the above mentioned U.S. Pat. No. 6,556,447 or U.S. Pat. No. 6,366,436, at least one feed through, for instance, in the form of a thin gap or a bore, is provided in the dividing walls correspondingly placed between the respective housing compartments for one or a number of electrical connecting elements serving to connect electrical components placed in a housing chamber to at least one electronic/electrical assembly placed in a neighboring housing chamber; for instance, the electrical connecting elements can be connecting lines and/or components of one or more plug connectors.

As a result of the numerous possible applications for electronic devices of the type being discussed, therefore industrial measuring and automation technology field devices, along with a corresponding multiplicity of possible characteristics of each of the device electronics to be used in the devices on the one hand, and the multiplicity of protection requirements actually fulfillable by the devices on the other hand, there is an increasing interest to develop, as indicated, among other things, in the previously mentioned US-A 2004/0183550 or U.S. Pat. No. 6,539,819, platform systems, for instance, electronics, which can be composed from as few individual modules, which are as largely uniform as possible, for devices of the type being discussed to meet the immensely high number of potential possibilities of embodiment resulting therefrom and, insofar as the corresponding types of individual devices to actually be stocked by a manufacturer of such devices, not least for the purpose of minimizing manufacturing and inventory costs. However this does not sufficiently solve equally the existing problem as regards the electronics housing—not least as a result of the numerous safety specifications, consequently the protection requirements to be fulfilled by the respective device and its electronics housing as a whole on the one hand, and the measures, which are most often very specific in detail and very complicated to implement, on the other hand—that for economic reasons the number of housing variants for electronic devices of the type being discussed to be provided would regularly be very high, since potentially universal solutions would be extremely expensive and would not be required for specific applications.

In accordance therewith, an object of the invention is to provide an electronics housing or a housing system, that with application a universal housing basic body can at least be optimally matched to different national or regional safety requirements, namely for different measurement principles and different protection, or safety requirements; the housing basic body should be usable with little supplemental effort, consequently with multiplicity of variants as small as possible as regards electronics, electronics installations, seals, potting measures, feed throughs etc., and with comparatively small additional storage, material and manufacturing costs, not least as regards the explosion safety of the respective field device or its safety against external penetration.

The invention achieves the object with an electronics housing for an electronic device embodied as a measuring and/or switching device for industrial measuring and automation technology, for example. The electronics housing of the invention comprises a housing basic body, for example, a pot shaped and/or monolithic, housing basic body, having a cavity, for example, a single cavity. The basic body includes: A side wall, for example, a metal and/or at least sectionally circularly cylindrical, side wall, laterally bounding the cavity of the basic body; an open end; and a rear wall, flat or outwardly convex for example, and bounding the cavity on an end lying opposite the open end and remote therefrom. The electronics housing further includes, releasably connected with the housing basic body on its open end, for example, by means of screwed connection, a housing lid sealing the basic body, for example, water spray tightly and/or explosion resistantly and/or in a manner satisfying the requirements of ignition protection type “Pressure resistant encapsulation (Ex-d);” the housing lid is, for example, screwed to the housing basic body and/or formed as a screw connection and/or has a viewing window. The electronics housing further includes an intermediate floor, for example, one at least sectionally circularly cylindrical and/or at least sectionally conical and/or formed as a screw in closure. The intermediate floor of the housing is inserted into the housing basic body and releasably affixed there, in the case of the electronics housing of the invention, to form a gap, circular or helical for example, extending between an inner surface of the side wall of the housing basic body and a lateral surface of intermediate floor of the housing facing the inner surface, as well as to form two housing chambers separated from one another in the cavity of the housing basic body by means of the intermediate floor of the housing; a first housing chamber is arranged in a chamber on a first side of the intermediate floor of the housing facing the housing lid for accommodating, for example, connection terminals for connecting lines leading out from the electronics housing and/or electrical assemblies satisfying ignition protection type “Increased Safety (Ex-e)” and/or ignition protection type “Intrinsic Safety (Ex-i)’, and a second housing chamber is arranged on a second side of the intermediate floor of the housing facing away from the housing lid for accommodating, for example, electronic components and/or satisfying an ignition protection type “Pressure Resistant Encapsulation (Ex-d).”

Moreover, the invention provides an electronic device, which comprises such an electronics housing as well as a device electronics accommodated therein.

Additionally, the invention also comprises such a device to be used for measuring a physical and/or chemical measured variable of a medium flowing in a pipeline, which, for example, at least sectionally extends through an explosion endangered danger zone, and/or of a medium in a container, which, for example, is placed within an explosion endangered danger zone.

According to a first embodiment of the electronics housing of the invention, it is additionally provided, that a greatest cross section of the intermediate floor of the housing is more than 50%, for example, more than 80%, of a largest inner cross section of the cavity of the housing basic body directly adjoining the housing lid, for example, and/or more than 50%, for example, more than 80%, of a largest cross section of the housing lid.

According to a second embodiment of the electronics housing of the invention, it is additionally provided that a volume portion of the cavity enclosed by the second housing chamber is at least 30%, for example, more than 50% and/or less than 90% of a total volume of the cavity of the housing basic body.

According to a third embodiment of the electronics housing of the invention, it is additionally provided that a volume portion of the cavity enclosed by the first housing chamber is smaller than a volume portion of the cavity enclosed by the second housing chamber.

According to a fourth embodiment of the electronics housing of the invention, it is additionally provided that the intermediate floor of the housing is removable from the cavity of the housing basic body, for example, only through its open end.

According to a fifth embodiment of the electronics housing of the invention, it is additionally provided that the intermediate floor of housing contacts the side wall via a lateral surface of the intermediate floor.

According to a sixth embodiment of the electronics housing of the invention, it is additionally provided that the lateral surface of the intermediate floor facing the inner surface of the side wall of the housing basic body has an external thread.

According to a seventh embodiment of the electronics housing of the invention, it is additionally provided that the inner surface of the side wall of the housing basic body has at least one internal thread.

According to an eighth embodiment of the electronics housing of the invention, it is additionally provided that the lateral surface of the intermediate floor facing the inner surface of the side wall of the housing basic body has an external thread, which is complementary with the internal thread provided in said inner surface and engages with the internal thread.

According to a ninth embodiment of the electronics housing of the invention, it is additionally provided, that at least one feed through, filled by means of a potting compound for example, is provided in the intermediate floor of the housing for at least one electrical connecting element, for example, a connecting line and/or a component of a plug connector, serving for connecting electrical components placed in the first housing chamber to at least one electronic assembly placed in the second housing chamber.

According to a tenth embodiment of the electronics housing of the invention, it is additionally provided that the side wall of the housing basic body has a surrounding, intermediate floor seat, which faces the cavity of the housing basic body, for example, a seat which is annular and/or has an internal thread on an inner side; the intermediate floor seat defines an opening, for example, a circular opening, corresponding to intermediate floor of the housing, into which opening the intermediate floor of the housing is inserted. Developing this embodiment of the invention further, it is additionally provided that the opening defined by the intermediate floor seat is circular, and wherein a midpoint of the opening is laterally spaced from an imaginary longitudinal axis of the housing basic body, extending for example, through a midpoint of the largest inner cross section of the cavity of the housing basic body directly adjoining the housing lid, and/or that at least one feed through, filled by means of potting compound for example, is provided in the intermediate floor-seat for an electrical connecting element, for example, a connecting line and/or a component of a plug connector, serving for connecting electrical components placed in the first housing chamber to at least one electronic assembly placed in the second housing chamber.

According to an eleventh embodiment of the electronics housing of the invention, it is additionally provided that an outer surface of the side wall of the housing basic body has at least one external thread, for example, in a border area adjacent to the open end; and/or that the inner surface of the side wall of the housing basic body has an internal thread in a border area adjacent to the open end. Developing this embodiment of the invention further, it is additionally provided that the housing lid is embodied as a screw connection with an internal thread that engages the external thread, or with an external thread that engages the internal thread in the border area.

According to a twelfth embodiment of the electronics housing of the invention, it is additionally provided that a shoulder, for example, a circumferential shoulder, is formed on the side wall of the housing basic body serving as a counterbearing for the intermediate floor of the housing. Developing this embodiment of the invention further, it is additionally provided that the side wall of the housing basic body has a groove, for example, a circumferential groove, placed between the shoulder and the housing lid on the inner surface of the housing basic body, and wherein the intermediate floor of the housing is held against the shoulder by means of a retaining ring placed in the groove. In another further development however, it is provided that the side wall of the housing basic body has an internal thread on its inner surface between the shoulder and the housing lid, and that the intermediate floor of the housing is held against the shoulder by means of a screw ring, formed for example, as a screw ring with an L-shaped cross section or as a ring with an angular cross section; the screw ring has an external thread, complementary to the internal thread and engaging therewith, on its lateral surface facing said inner surface. A gap formed between the screw ring and side wall of the housing basic body or a gap formed between the screw ring and intermediate floor of the housing can, in such a case, be embodied in an advantageous manner so that a spreading of an explosion arising in the second housing chamber into the first housing chamber, for example, also with an explosion pressure greater than 20 bar, is prevented by said gap and/or that it satisfies the requirements of ignition protection type “Pressure Resistant Encapsulation (Ex-d)”.

According to a thirteenth embodiment of the electronics housing of the invention, it is additionally provided that the gap formed between the side wall of the housing basic body and the intermediate floor of the housing satisfies the requirements of ignition protection type “Pressure Resistant Encapsulation (Ex-d)”.

According to a fourteenth embodiment of the electronics housing of the invention, it is additionally provided that the gap formed between the side wall of the housing basic body and the intermediate floor of the housing is so embodied that a spreading of an explosion arising in the second housing chamber, for example, also with an explosion pressure greater than 20 bar, into the first housing chamber, is prevented by said gap.

According to a fifteenth embodiment of the electronics housing of the invention, it is additionally provided that the gap formed between the side wall of the housing basic body and the intermediate floor of the housing has a minimum gap depth, which is greater than 10 mm. Developing this embodiment of the invention further, it is additionally provided that the gap formed between the side wall of the housing basic body and the intermediate floor of the housing has a maximum gap width, which is at most 0.2 mm, throughout a gap depth of greater than 10 mm.

According to a sixteenth embodiment of the electronics housing of the invention, it is additionally provided that the housing basic body and intermediate floor of the housing are so embodied and affixed to one another that at least the second housing chamber withstands an explosion arising in the second housing chamber, with a pressure greater than 20 bar, for example, greater than 60 bar, without damage.

According to a seventeenth embodiment of the electronics housing of the invention, it is additionally provided, that the housing basic body and housing lid are so embodied and affixed to one another that the electronics housing withstands, without damage, an explosion with a pressure greater than 20 bar, for example, greater than 60 bar, arising, for example, in the first housing chamber.

According to an eighteenth embodiment of the electronics housing of the invention, it is additionally provided that in the intermediate floor of the housing at least one feedthrough, filled by means of potting compound, for example, is provided for electrical connecting lines serving for connecting electrical components placed in the first housing chamber to at least one electronic assembly placed in the second housing chamber.

According to a nineteenth embodiment of the electronics housing of the invention, it is additionally provided that a rear and side wall of the housing basic body are connected to one another by a material bond.

According to a twentieth embodiment of the electronics housing of the invention, it is additionally provided that the housing basic body is monolithic, in that the rear and side walls are connected to one another joint freely.

According to a twenty-first embodiment of the electronics housing of the invention, it is additionally provided that the housing basic body at least partially, completely, for example, comprises a pressure cast material and/or aluminum.

According to a twenty-second embodiment of the electronics housing of the invention, it is additionally provided that the housing basic body at least partially, completely, for example, comprises an investment cast material and/or stainless steel.

According to a twenty-third embodiment of the electronics housing of the invention, it is additionally provided that the side wall of the housing basic body surrounding a section in the second housing chamber is provided with at least one feedthrough opening for electrical connecting lines serving for electrical, for example, galvanic, connection of electrical and/or electronic components placed in the second housing chamber to at least one electrical component, for example, a resistor and/or a coil and/or a capacitor, placed outside of the electronics housing.

According to a twenty-fourth embodiment of the electronics housing of the invention, a section of the side wall of the housing basic body surrounding the first housing chamber is provided with at least one feed through opening for electrical connecting lines serving for the electrical, for example, galvanic, connection of electrical components placed in the first housing chamber, for example, connection terminals, to at least one electrical component, for example, an external energy supply, placed outside the electronics housing.

According to a twenty-fifth embodiment of the electronics housing of the invention, it is additionally provided that the first housing chamber extends from the first side of the intermediate floor of the housing to an inner side of the housing lid facing the cavity of the housing basic body.

According to a twenty-sixth embodiment of the electronics housing of the invention, this further comprises a partition sealing, for example, hermetically sealing, the first housing chamber on a side facing the housing lid; wherein the partition is placed between the first housing chamber and the housing lid; wherein, the partition is, for example, removable again from the housing basic body, following removal of the housing lid, via the open end of the housing basic body and/or the partition is metal; the partition serves to form a third housing chamber between a first side of said partition facing the housing lid and extending to an inner side of the housing lid facing the cavity of the housing basic body; the third housing chamber, for example, accommodates electrical assemblies satisfying a penetration protection type “water spray protected (IP54)” and/or an ignition protection type “Intrinsic Safety (Exi)”.

According to a first embodiment of the electronic device of the invention, it is additionally provided that the electronic device further comprises a measuring transducer electrically connected, for example, galvanically connected, by means of a connecting line to at least one electronic assembly placed in the second housing chamber; during operation, the measuring transducer provides, for example, via a connecting line connected to the device electronics, at least at times a measurement signal corresponding to a physical and/or chemical measured variable of a medium, for example, a medium in a pipeline and/or in a container.

According to a second embodiment of the electronic device of the invention, it is additionally provided that at least one electrical component and/or an electronic assembly is/are placed on the second side of the intermediate floor of the housing, for example, at least partially embedded in a potting compound provided on said side of the intermediate floor.

Based on the previously mentioned disadvantages of conventional electronics housings, and consequently inherent in the electronic devices formed therewith, namely the potentially high manufacturing costs for universal electronics housings, namely simultaneously different ones and, in given cases, however, ones satisfying safety and protection requirements not even required, a basic idea of the invention is to provide a building block system for an electronics housing of the type being discussed with a first housing basic body—here essentially pot shaped—having at least a single largely barrier free lumen reachable from the open end preferably all the way to the rear wall; the housing basic body, with application of a special intermediate floor matched to the safety and protection requirements for different protection and safety requirements of the housing, can be completed as an electronics housing, which has chambers separated from one another for different electrical or electronic components or assemblies formed therewith. An advantage of the invention is, among other things, that with some few variants for housing basic body and intermediate floor, for instance, different in regard to the materials used, nevertheless variants largely compatible with one another, equally with comparatively low storage and manufacturing costs as well, a very high multiplicity of variants of electronics housings can be made available; the multiplicity of variants also exactly meet very particular safety and protection requirements and provides very cost effectively adapted electronics housings.

In particular, there are a large number of options available to embody and to further develop the devices of the invention as well as uses of such devices of the invention. In this regard, reference is made to the patent claims dependent on the independent patent claims as well as to the following explanation of the invention, as well as to advantageous embodiments of the same based on examples of embodiments illustrated in the figures of the drawing; equal parts are provided with equal reference characters in the figures. If it is helpful for clarity, reference characters already used are omitted in subsequent figures. The figures of the drawing show as follows:

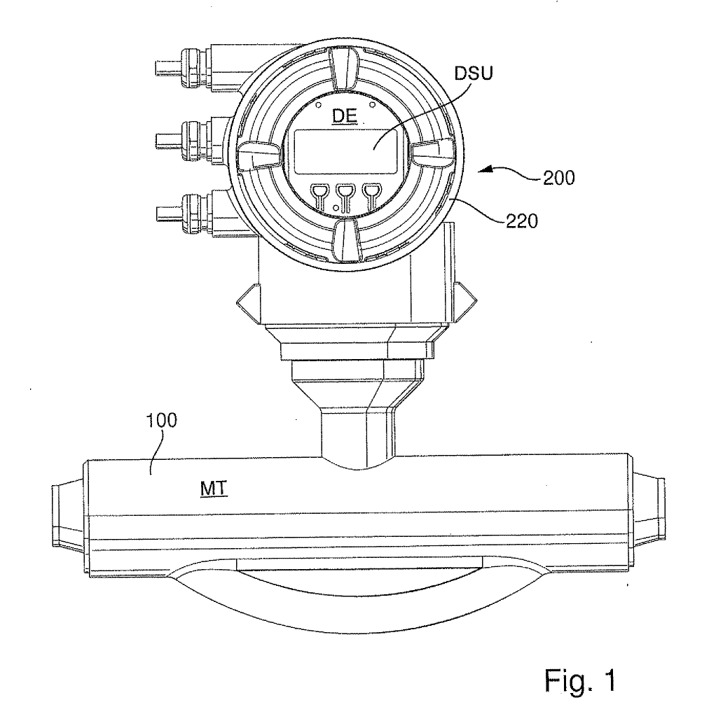

FIG. 1 a side view of an electronic device with an electronics housing formed as a field device, especially a Coriolis mass flow measuring device;

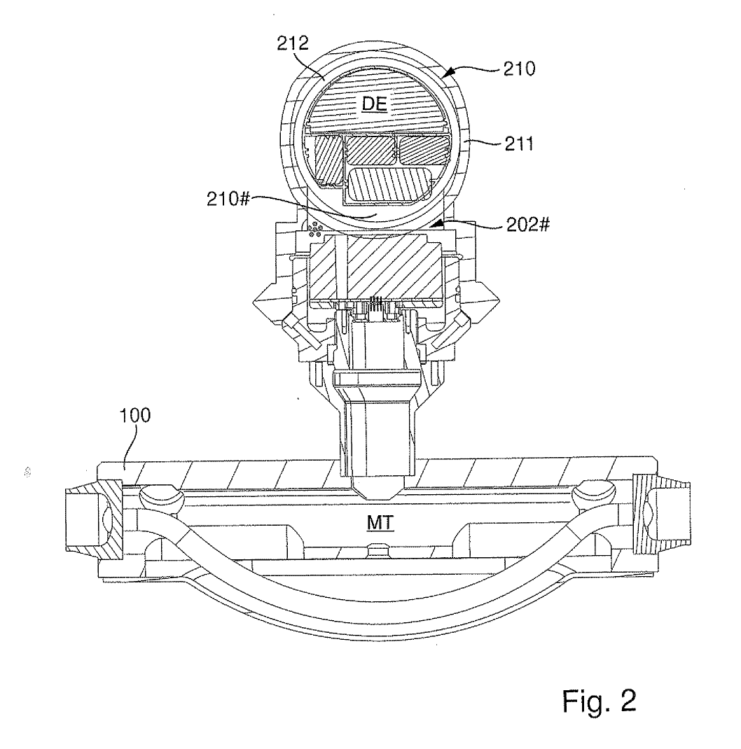

FIGS. 2,3 In section, two different views of the device of FIG. 1;

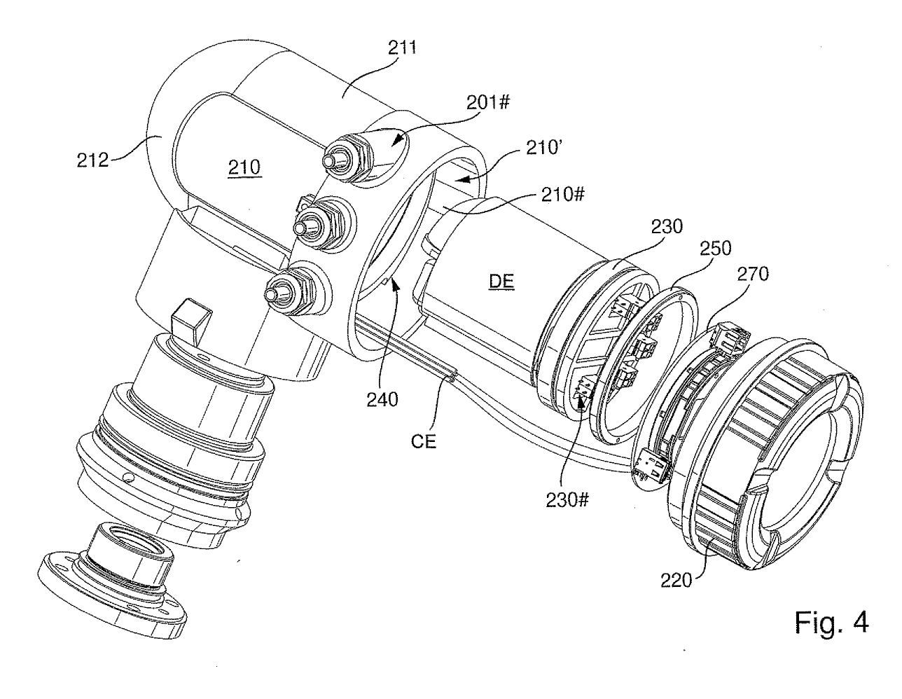

FIGS. 4,5 electronics housing suitable for a device according to

FIG. 1, perspectively in two different, partially sectioned side views; and

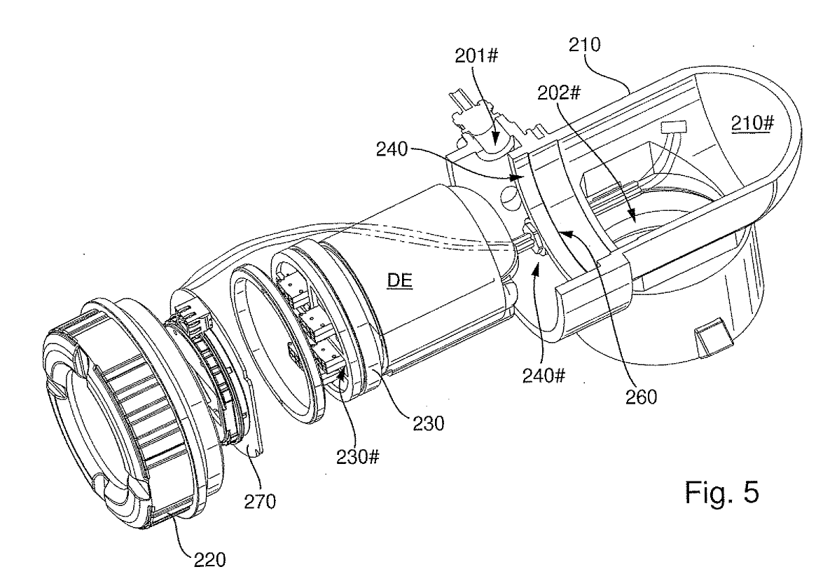

FIG. 5 a view of a variant for an electronics housing suitable for a device according to FIG. 1.

An electrical electronic device, especially one embodied as a measuring and/or switching device for industrial measuring and automation technology, is shown in different views in FIGS. 1, 2 and 3. The device comprises, as directly evident from the combination of FIGS. 1, 2 and 3, an electronics housing 200, which is formed by means of a housing basic body 210—here essentially pot shaped—having a cavity 210# and an open end 210′ and a housing lid 220 releasably connected to the open end 210′ of the housing basic body and sealing this, for example, water spray tightly or in given cases also dust tightly and/or explosion resistantly. The cavity 210# serves, among other things, also to accommodate electrical and/or electronic components, and, respectively, therewith formed, component assemblies of the device connected together to a corresponding device electronics DE, for example, also component assemblies encapsulated in electronics inserts and/or embedded in a potting compound of synthetic material, such as, for instance, polyurethane, silicone, epoxide resin or the like, especially also to protect the same against environmental influences or contact. The housing basic body 210 has a side wall 211 laterally bordering its cavity 210#, especially a side wall of metal and/or a side wall, which is at least sectionally circularly cylindrical, with an open end and a rear wall 212 bounding the cavity on an end lying opposite the open end and remote therefrom, especially a flat or outwardly convex, rear wall 212. The housing basic body can be, for example, monolithic, in which case the rear and side walls are connected to one another joint freely; rear and side walls of the housing basic body, completely made of aluminum or completely made of stainless steel, for example, can, for example, however, also be connected to one another with a material bond, for instance, by means of a corresponding weld seam. Particularly in the case of a monolithic housing basic body, namely one free of joints, this housing basic body can be, for example, of a pressure cast material, for instance, compression molded aluminum, or an investment cast material, for instance, stainless steel.

The housing lid 220—here likewise having an essentially circular shaped cross section—as also presented schematically in FIG. 1, can additionally be equipped with a viewing window and/or be connected to the housing basic body 210 by means of a screw connection. For such a purpose, the housing lid 220, as is quite usual in the case of electronic devices of the type being discussed, for example, can even be embodied as a screw connection; it can, however, for example, also be affixed to the housing basic body by means of screws, which are inserted through bores in its rim and are screwed into corresponding internal threaded bores. For such a purpose, an outer surface 211′ of the side wall 211 of the housing basic body has at least one external thread, especially in an edge region adjacent to the open end according to an embodiment of the invention, and/or the inner surface 211″ of the side wall 211 of the housing basic body has an internal thread in an edge region adjacent to the open end according to another embodiment. The housing lid 220 is additionally embodied, in such a case, as a screw connection, which—, depending on the selected embodiment of the housing basic body—has an internal thread in its edge region to engage the external thread, or an external thread in its edge region to engage the internal thread.

If required, the housing lid 220 and housing basic body 210 can additionally be so embodied, for instance, through application of a sufficiently solid material and corresponding material thicknesses, and—not the least also under ensuring the gap size required for flame penetration and explosion safety—can be connected with one another so that the housing basic body 210 can be sealed by means of the housing lid 220 ultimately in a manner sufficient for the requirements according to ignition protection type “Pressure Resistant Encapsulation (Ex-d)”, or that the electronics housing 200 withstands an explosion pressure, possibly arising therein, of more than 20 bar, especially more than 60 bar, without damage.

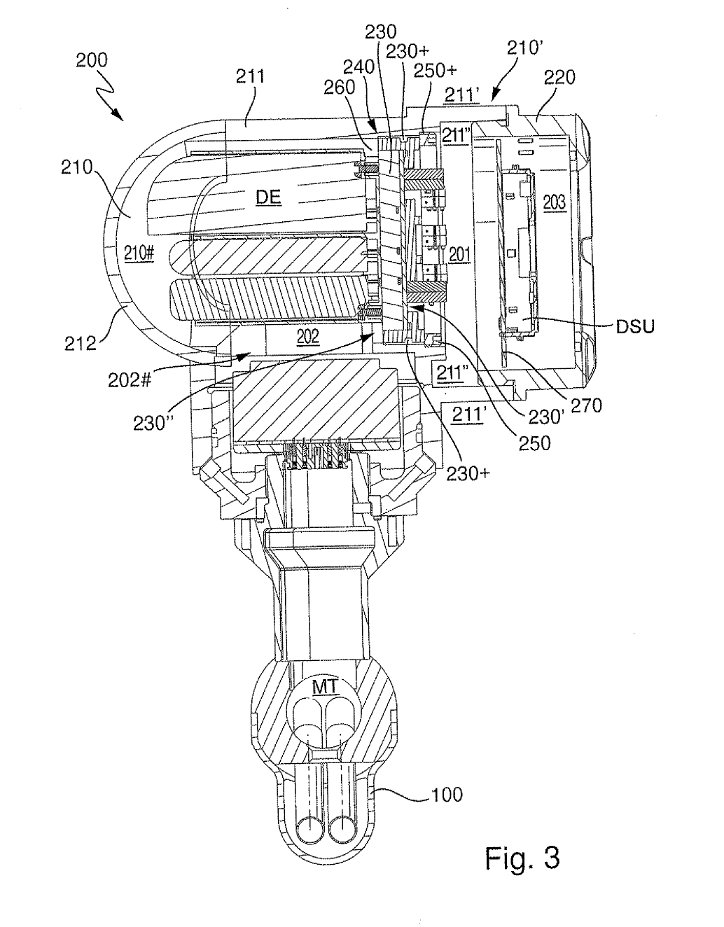

The electronic device is especially additionally intended for measuring a physical and/or chemical measured variable of a medium in, for example, a pipeline extending at least sectionally through an explosion endangered danger zone, and/or in a container, for example, placed within an explosion endangered danger zone. Accordingly, the electrical device can be, for example, a magneto inductive flow measuring device, a vortex flow measuring device, an ultrasound flow measuring device, a thermal mass flow measuring device, a pressure measuring device, a fill level measuring device, a temperature measuring device, a pH value measuring device, a conductivity measuring device or, by way of example, a Coriolis mass flow measuring as only schematically presented in FIGS. 1, 2 and 3. According to a further development of the invention, the electronic device accordingly comprises at least one measuring transducer MT electrically connected, especially galvanically connected, to electronic components placed in the electronics housing, or to at least one electronic assembly formed therewith, by means of, for example, a sectionally flexible connecting line; during operation, the measuring transducer MT at least at times provides via a connecting line, for instance, for an electronic measuring and evaluating circuit formed by means of electronic components placed in the electronics housing, for example, in the form of a microcomputer, at least one measurement signal corresponding to a physical and/or chemical measured variable of the respective medium to be measured, especially a medium in a pipeline and/or in a container. As evident from FIGS. 2 and 3, for example, a measuring transducer of vibration type with two parallel, bent measuring tubes, which are actively excited to mechanical oscillations by means of an electromechanical oscillation exciter acting thereon during operation for the purpose of producing at least one measurement signal, can serve as the measuring transducer MT. For visualizing measured values (for instance, mass flow measured values, density measured values, viscosity measured values, volume flow measured values, pH measured values, temperature measured values, pressure measured values, etc.) produced internally by the device, and/or, in given cases, status reports generated internally by the device such as, for instance, an error report relevant to the device or an alarm concerning the medium or the process to be monitored, on-site, in a further development of the invention, the device additionally comprises a display and service unit DSU communicating at least at times with the device electronics, for instance, a DSU having an LCD- or TFT display placed in the electronics housing directly behind the viewing window provided in given cases in the housing lid and/or a DSU with integrated non volatile data memory for measurement and/or for configuration data.

In operation, the electronic device is connected to an external electrical energy supply, which is remote from the device in given cases. The connecting lines used for this can be led, as is evident from the combination of FIGS. 1, 4 and 5, from, for example, each electrical component, consequently components of an energy supply and/or of a superordinated data processing system, placed outside the electronics housing and to be connected, via feed throughs (201#) provided in the edge region of the open end of the housing basic body, into the cavity and be electrically connected to connection terminals correspondingly placed therein and in connection, for example, with an internal supply circuit and/or a modem of the device.

The electronics housing of the invention, consequently also the electronic device formed therewith, additionally comprises, as schematically presented in FIGS. 4 and 5, an intermediate floor 230 of the housing formed, for example, at least sectionally circularly cylindrically and/or at least sectionally conically and/or as a screw in closure. As evident from the combination of FIGS. 1 to 5, this intermediate floor 230 of the housing, in forming a gap 230+—here circularly orbiting or, however, also helically winding—extending between an inner surface of the side wall of the housing basic body and a lateral surface of the intermediate floor 230 of the housing facing this, is inserted in the housing basic body and releasably affixed therein in such a manner that, as a result, two housing chambers, separated from one another, are formed by means of the (installed) intermediate floor of the housing in the cavity of the housing basic body. It is especially additionally provided that the housing basic body and intermediate floor of the housing are so dimensioned that latter is removable from the cavity of the housing basic body through its open end, especially also in such a manner that the intermediate floor 230 of the housing is removable only through the open end 210′ of the housing basic body 210, however, not removable through possible other openings, for instance, openings formed in the side wall of the housing basic body.

Of the two chambers separated from one another by means of the intermediate floor 230 of the housing, a first housing chamber 201 is arranged on a first side, namely the side of the intermediate floor facing the housing lid of the housing, and accommodates for example, connection terminals for connecting lines leading out from the electronics housing and/or electrical components satisfying the ignition protection type “Increased Safety (Ex-e)” and/or an electrical assembly satisfying the ignition protection type “intrinsic safety (Ex-i)”, and a second housing chamber 202 is arranged on a second side, namely the side of the intermediate floor 230 of the housing facing away from housing lid and accommodates electronic components and/or satisfies the ignition protection type “Pressure Resistant Encapsulation (Ex-d)”. The first housing chamber 201 can extend, for example, from the first side 230′ of the intermediate floor of the housing to the edge region defined by the open end of the housing basic body, or to an inner side 220′ of the housing lid facing the cavity of the housing basic body, while an end of the second housing chamber, as is evident from FIGS. 3 to 5, can be formed by the rear wall of the housing basic body. For the case shown here, in which the device electronics is to be connected to a measuring transducer, and corresponding to an additional embodiment of the invention, at least one feed through opening 202# is additionally provided in a section of the side wall of the housing basic body 211 surrounding the second housing chamber 202 for electrical connecting lines serving for electrical, galvanic for example, connection of electrical and/or electronic components placed in the second housing chamber 202 to at least one electrical component placed outside the electronics housing; for example, an electrical resistor and/or a coil and/or a capacitor—installed here in the measuring transducer MT. For the case shown here, in which the measuring transducer MT is additionally also connected mechanically, especially rigidly, to the housing basic body, consequently with the electronics housing as a whole, the feed through opening is additionally provided with a corresponding connecting flange for an connecting flange complementary to the measuring transducer, for example, a complementary connecting flange affixed to a measuring transducer housing 100 via a neck piece.

According to an additional embodiment of the invention, a greatest cross section of the intermediate floor of the housing is more than 50%, especially more than 80%, and less than 95% of a largest inner cross section of the cavity of the housing basic body, especially directly adjoining the housing lid, or is more than 50%, especially more than 80%, and less than 95% of a largest cross section of the housing lid. In this way, it is possible to reach, largely barrier free, or simply withdraw, defective assemblies or assemblies to be replaced for the purpose of device upgrading, even assemblies placed within the second chamber, after the removal of the housing lid and thereafter the intermediate floor of the housing from the housing basic body, for example, for the purpose of an exchange of other such assemblies on-site, or, conversely, to insert such an assembly back into the housing basic body on-site in simple manner. In order to enable an easy insertion and affixation of the intermediate floor of the housing, the side wall of the housing basic body comprises, according to an additional embodiment of the invention, an orbiting, for example, also annular, intermediate floor-seat 240 facing the cavity; the intermediate floor-seat 240 defines an opening 240# corresponding to the intermediate floor of the housing, especially a circular opening, sufficiently large for the insertion of the intermediate floor of the housing with electronic assemblies held thereto; the intermediate floor of the housing is inserted in its installed position into the opening 240#. For the purpose of simplifying a removal or installation of electronic assemblies it can be additionally advantageous, as indicated in FIGS. 4 and 5, to mount the electronic assemblies directly on the intermediate floor, consequently to correspondingly affix them to its second side. In accordance therewith, according to an additional embodiment of the invention, at least one electrical component and/or an electronic assembly is placed on the second side of the intermediate floor of the housing, for example, completely or partially embedded in a potting compound provided on said side of the intermediate floor of the housing and/or releasably affixed to the intermediate floor of the housing, for instance, by means of plug connectors. Alternatively or in supplementation, at least one feed through 230#, filled by means of potting compound, for example, is additionally provided in the intermediate floor of the housing for at least one electrical connecting element, especially a connecting line and/or a component of a plug connector, serving for connecting electrical components placed in the first housing-chamber to at least one electronic assembly placed in the second housing chamber.

According to an additional embodiment of the invention, and evident from the combination of FIGS. 3, 4 and 5, the housing basic body and intermediate floor of the housing can be so dimensioned and the intermediate floor so placed in its installed position in the housing basic body so that the side wall is contacted by the lateral surface of the intermediate floor of the housing to form a connection of the housing basic body and the intermediate floor of the housing acting as a loose fit connection, especially in such a manner that the gap corresponds to the required dimensions as regards gap width, length and depth for the ignition protection type “Pressure Resistant Encapsulation (Ex-d)”, for instance, required by EN 60079-1:2007 or also the international standard IEC 60079-2:2007, and insofar the gap and intermediate floor of the housing, in each case, satisfy the requirements of ignition protection type “Pressure Resistant Encapsulation (Ex-d),” Developing this aspect of the invention further, according to an additional embodiment of the invention, the housing basic body and intermediate floor of the housing are additionally so embodied and affixed to one another that at least the second housing chamber withstands a therein arising explosion pressure of more than 20 bar, especially more than 60 bar, without damage, or that the gap created between the side wall of the housing basic body and the intermediate floor of the housing is embodied so that a spreading of an explosion arising in the second housing chamber, especially also with an explosion pressure of more than 20 bar, into the first housing chamber via said gap is prevented.

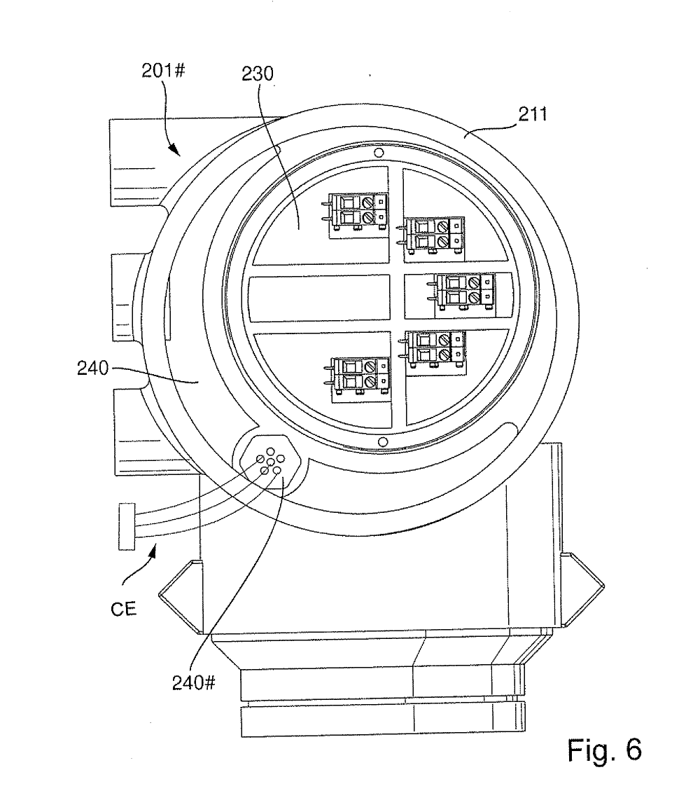

For such purpose, according to an additional embodiment of the invention, the intermediate floor of the housing and the housing basic body are so embodied that the gap formed between its side wall and the intermediate floor of the housing—measured in the direction of an imaginary longitudinal axis of the housing basic body, which extends, for example, through a midpoint of the largest inner cross section of the cavity of the housing basic body directly adjoining the housing lid and a midpoint of the rear wall of the housing basic body,—has a minimum gap depth, which amounts to more than 10 mm, or a gap depth of more than 10 mm, and has a maximum gap width—measured as a radial distance between the said lateral surface of the intermediate floor of the housing and the side wall of the housing basic body—, which is no greater than 0.2 mm. In an additional embodiment, it is provided that the gap 230+, especially sufficiently for the requirements of ignition protection type “Pressure Resistant Encapsulation (Ex-d)”, is formed by means of a number of thread courses, for instance, in such a manner, that at least the lateral surface of the intermediate floor of the housing facing the inner surface of the side wall of the housing basic body has an external thread, and/or that at least the inner surface of the side wall of the housing basic body has at least one internal thread, and/or the gap 230+ is formed in such a manner that the lateral surface of the intermediate floor of the housing facing the inner surface of the side wall of the housing basic body has an external thread complementary to the internal thread provided in said inner surface and engaging therewith. In the latter case, the intermediate floor of the housing is additionally designed to be screwed together with the housing basic body, for instance, as a screw type closure, by means of the aforementioned internal/external threads. For the case mentioned, in which the side wall has an intermediate floor seat on its inner wall for the purpose of accommodating the intermediate floor of the housing—alternatively or supplementally to the internal thread mentioned above—an internal thread correspondingly interacting in turn, in given cases, further, for example, with the intermediate floor of the housing formed as a screw connection is arranged on an inner side of the intermediate floor seat 240 corresponding to the lateral surface of the installed intermediate floor of the housing according to another embodiment of the invention. Particularly for this case of the application of the intermediate floor of the housing as a type of screw closure, in advantageous manner in the intermediate floor seat at least a feed through 240#, also filled by means of potting compound for example, can additionally be provided for at least one electrical connecting element CE, for example, thus a connecting line and/or a component of a plug connector, serving for connecting electrical components placed in the first housing chamber 201 to an electronic assembly placed in the second housing chamber 202. Additionally, in such case, for instance, for the optimal exploitation of the installation space offered within the housing basic body, for as large a cross section of the intermediate floor 230 of the housing as possible on one hand, and for a sufficiently large cross section for the aforementioned feed through 240# in the intermediate floor seat on the other hand, it can be advantageous when, as is evident from FIG. 6, a midpoint of the opening defined by the intermediate floor-seat, consequently a circularly shaped opening, is laterally spaced from a longitudinal axis of the housing basic body, for instance, extending through a midpoint of the largest inner cross section of the cavity of the housing basic body directly adjoining the housing lid or the imaginary cross section mentioned above; thus as a result, two eccentric circles are formed by the open end of the housing basic body and the circular opening surrounded by the intermediate floor seat.

Alternatively to the aforementioned application of the intermediate floor of the housing as a type of screwed closure, the opportunity further also exists to construct or use the intermediate floor of the housing as type of stopper. For such a purpose, according to another embodiment of the invention, a shoulder 260, especially a circular shoulder, is formed on the side wall 211 of the housing basic body serving as counterbearing for the intermediate floor of the housing; the intermediate floor of the housing, in its installed position, is held pressed against the shoulder 260, for instance, by a retaining ring. For this case, a groove, especially a circular groove, is provided in the inner surface of the side wall of the housing basic body placed between the shoulder and the housing lid; in turn, into the groove is placed correspondingly the retaining ring holding the intermediate floor of the housing in its installed position against the shoulder 260. Alternatively thereto, as is also evident from the combination of FIGS. 3, 4 and 5, the intermediate floor of the housing can be held pressed against the shoulder in its installed position, however, for example, by means of a screw ring 250, for instance, formed with an L-shaped cross section or as a ring with an angular cross section; the screw ring 250 has an external thread facing a lateral surface of the inner surface the side wall; the external thread engages with an internal thread provided in the side wall, complementary to said external thread. Additionally, the housing basic body, intermediate floor of the housing and retaining ring can be embodied in this case so that the gap 250+ formed between the screw ring and side wall of the housing basic body or the gap equally formed between the screw ring and intermediate floor of the housing is embodied so that a spreading of an explosion arising in the second housing chamber, especially also with an explosion pressure of more than 20 bar, into the first housing chamber via said gap is prevented and/or that it satisfies the requirements of ignition protection type “Pressure Resistant Encapsulation (Ex-d).”

Particularly for the case in which the first chamber 201 mainly serves as a connection space, namely for accommodating connection terminals for connecting lines leading out from the electronics housing—here lateral feed throughs 201# provided in the edge region of the open end of the housing basic body, for example, also implemented according to protection class/type IP54 or IP68—for instance, for the external energy supply mentioned, while the second chamber 202 is mainly provided as an electronics compartment, namely for accommodating at least the predominant part of the electronic components/assemblies forming the device electronics, it can be of advantage to provide the two chambers with different capacities, for instance, in such a manner, that a volume portion of the cavity enclosed by the first housing chamber 201 is smaller than a volume portion of the cavity enclosed by the second housing chamber 202. Accordingly, in an additional embodiment of the invention, the intermediate floor is so placed in the housing basic body that the volume portion of the cavity enclosed by the second housing chamber amounts to at least 30%, especially more than 50%, as is also directly evident from the combination of FIGS. 4 and 5. Nevertheless, in order to hold ready a sufficient space for possibly providing a display/operating element DSU in the first chamber, it is additionally provided that the volume portion of the cavity enclosed by the second housing chamber is, however, ultimately less than 90% of said total volume of the cavity of the housing basic body.

For the purpose of the separate accommodation of the mentioned display and interaction unit DSU, for example, one satisfying the ignition protection type “Intrinsic Safety (Exi),” to be regularly removed at times, for instance, in the course of a software update and/or a parametering of the device electronics performed on site, the electronics housing further comprises, in an additional development of the invention, a sealing (for example, dust or water spray tightly) partition 270 placed on a side facing the housing lid, between the first housing chamber and the housing lid, to form a third housing chamber 203 extending between a first side of said partition facing the housing lid and an inner side of the housing lid facing the cavity of the housing basic body. The partition 270, in the form of a thin metal plate for example, is especially provided to be able to be taken back out, after taking off the housing lid, from the housing basic body 210 via the open end 210′ of the housing basic body, for instance, for the purpose of reaching the housing chamber(s) 201, or 202 lying behind the partition 270.

1-22. (canceled)

23. An electronics housing, especially for an electronic device embodied as a measuring and/or switching device of industrial measuring and automation technology which electronics housing comprises:
a housing basic body, especially a pot shaped and/or monolithic one, having a cavity, especially a single cavity, wherein said basic body includes: a side wall, especially a metal and/or at least sectionally circularly cylindrical side wall, laterally bordering said cavity; an open end; and a rear wall, especially a flat or outwardly convex rear wall, bounding said cavity on an end lying opposite the open end and remote therefrom;
a housing lid, especially a housing lid screwed to said housing basic body and/or formed as a screw connection and/or having a viewing window, releasably connected to said housing basic body on its open end, especially by means of a screwed connection, and sealing said basic body, especially water spray tightly and/or explosion resistant and/or in a manner satisfying the requirements for ignition protection type “Pressure Resistant Encapsulation (Ex-d);” and
an intermediate floor, especially an at least sectionally circularly cylindrical intermediate floor and/or one at least sectionally conical and/or formed as a screw in closure, wherein:
said intermediate floor is inserted into and releasably affixed to said housing basic body to form a gap extending, especially circularly or helically, between an inner surface of said side wall of said housing basic body and a lateral surface of said intermediate floor of the housing facing such inner surface; as well as two housing chambers in said cavity of said housing basic body separated from one another by means of said intermediate floor, of which a first housing chamber, especially a first housing chamber accommodating connection terminals for connecting lines leading out from the electronics housing and/or electrical components satisfying an ignition protection type (Ex-e)” and/or electrical assemblies satisfying an ignition protection type “Intrinsic Safety (Exi)”, is arranged on a first side of said intermediate floor of the housing facing said housing lid and a second housing chamber, especially a second housing chamber accommodating electronic components and/or satisfying an ignition protection type “Pressure Resistant Encapsulation (Ex-d)”, arranged on a second side of said intermediate floor of the housing facing away from said housing lid.

24. The electronics housing as claimed in claim 23, wherein:
a greatest cross section of said intermediate floor of the housing is greater than 50%, especially greater than 80%, of a largest inner cross section of said cavity, especially directly adjoining said housing lid, of said housing basic body and/or is greater than 50%, especially greater than 80%, of a largest cross section of said housing lid; and/or
a volume portion of said cavity enclosed by said second housing chamber is at least 30%, especially greater than 50% and/or less than 90%, of a total volume of said cavity of said housing basic body; and/or
a volume portion of said cavity enclosed by said first housing chamber is smaller than as a volume portion of said cavity enclosed by said second housing chamber; and/or
said intermediate floor of the housing is removable from said cavity of said housing body, especially through its open end only; and/or
a lateral surface of the intermediate floor of the housing contacts the side wall; and/or
the lateral surface of said intermediate floor facing the inner surface of said side wall of said housing basic body has an external thread.

25. The electronics housing as claimed in claim 23, wherein:
said inner surface of said side wall of said housing basic body has at least one internal thread.

26. The electronics housing as claimed in claim 25, wherein:
said lateral surface of said intermediate floor of the housing facing the inner surface of said side wall of said housing basic body has an external thread complementary to the internal thread provided in said inner surface and engages therewith.

27. The electronics housing as claimed in claim 23, wherein:
the side wall of said housing basic body has an intermediate floor seat, especially an annular intermediate floor seat facing its cavity, said floor seat defines an opening, especially a circular opening, corresponding to said intermediate floor; and said intermediate floor is set into said opening.

28. The electronics housing as claimed in claim 25, wherein;
said internal thread is arranged on an inner side of said intermediate floor seat corresponding to the lateral surface of the installed intermediate floor.

29. The electronics housing as claimed in claim 27, further comprising:
at least one feed through, especially one filled by means of a potting compound, in said intermediate floor seat for an electrical connecting element, especially a connecting line and/or a component of a plug connector, serving to connect electrical components placed in said first housing chamber to at least one electronic assembly placed in said second housing chamber; and/or wherein:
said opening defined by said intermediate floor seat is circular, and wherein a midpoint of said opening is laterally spaced from an imaginary longitudinal axis of said housing basic body, especially a longitudinal axis extending through a midpoint of the largest inner cross section of said cavity of said housing basic body directly adjoining said housing lid.

30. The electronics housing as claimed in claim 23, wherein;
an outer surface of the side wall of said housing basic body, especially in an edge region bordering the open end, has at least one external thread; and/or
the inner surface of the side wall of said housing basic body has an internal thread in an edge region bordering the open end.

31. The electronics housing as claimed in claim 30, wherein:
said housing lid is embodied as a screw connection with an internal thread that engages the external thread in the edge region, or with an external thread that engages the internal thread in the edge region.

32. The electronics housing as claimed in claim 23, wherein:
a shoulder, especially a circular shoulder, is formed on the side wall of said housing basic body serving as a counterbearing for said intermediate floor.

33. The electronics housing as claimed in claim 33, wherein:
the side wall of said housing basic body has an internal thread placed on its surface between the shoulder and the housing lid;
said intermediate floor is held pressed against said shoulder by means of a screw ring, especially one with an L-shaped cross section or formed as a ring with an angular cross section;
said screw ring has an external thread on a lateral surface facing said inner surface; and
said external thread is complementary to said internal thread and engages therewith.

34. The electronics housing as claimed in claim 33, wherein:
said gap formed between said screw ring and side wall of said housing basic body is embodied so that spread of an explosion, especially also with an explosion pressure of more than 20 bar, arising in said second housing chamber into said first housing chamber via said gap is prevented and/or that said gap satisfies the requirements of ignition protection type “Pressure Resistant Encapsulation (Ex-d).”

35. The electronics housing as claimed in claim 34, wherein:
said gap formed between said screw ring and intermediate floor is embodied so that spread of an explosion, especially also with an explosion pressure of more than 20 bar, arising in said second housing chamber into said first housing chamber via said gap is prevented and/or that the gap satisfies the requirements of ignition protection type “Pressure Resistant Encapsulation (Ex-d).”

36. The electronics housing as claimed in claim 32, wherein:
said side wall of said housing basic body has a groove, especially a circular groove, on its inner surface placed between said shoulder and said housing lid; and
said intermediate floor is held pressed against said shoulder by means of a retaining ring placed in the groove.

37. The electronics housing as claimed in claim 23, wherein:
said gap formed between the side wall of said housing basic body and said intermediate floor satisfies the requirements of ignition protection type “Pressure Resistant Encapsulation (Ex-d)”; and/or
said gap formed between the side wall of said housing basic body and said intermediate floor is embodied so that a spreading of an explosion, especially also with an explosion pressure of more than 20 bar, arising in said second housing chamber into said first housing chamber via said gap is prevented; and/or
said gap formed between the side wall of the housing basic body and the intermediate floor has a minimum gap depth, which is greater than 10 mm, especially in such a manner, that the gap formed between the side wall of said housing basic body and said intermediate floor, throughout a gap depth of greater than 10 mm, has a maximum gap width, which is less than 0.2 mm; and/or
said housing basic body and said intermediate floor are so embodied and affixed to one another that at least said second housing chamber withstands without damage an explosion pressure of greater than 20 bar, especially greater than 60 bar, arising therein; and/or
said housing basic body and said housing lid are embodied and affixed to one another so that the electronics housing withstands an explosion pressure arising therein, especially in said first housing chamber, of greater than 20 bar, especially greater than 60 bar, without damage; and/or
said intermediate floor is provided with at least one feed through, especially one filled by means of a potting compound, for electrical connecting lines serving for connecting electrical components placed in said first housing chamber to at least one electronic assembly placed in said second housing chamber; and/or
said intermediate floor is provided with at least one feed through, especially one filled by means of a potting compound, for at least one electrical connecting element, especially a connecting line and/or a component of a plug connector, serving for connecting electrical components placed in said first housing chamber to at least one electronic assembly placed in said second housing chamber.

38. The electronics housing as claimed in claim 23, wherein:
the rear and side walls of said housing basic body interlock with one another and are connected by a material bond; and/or
said housing body is a monolith, in the case of which the rear and side walls are connected to one another joint freely; and/or
said housing basic body at least partially, especially completely, comprises a pressure cast material and/or aluminum; and/or
said housing basic body at least partially, especially completely, comprises an investment cast material and/or stainless steel.

39. The electronics housing as claimed in claim 23, wherein:
a section of the side wall of said housing basic body surrounding said second housing chamber is provided with at least one feed through opening for electrical connecting lines serving the electrical, especially galvanic, connection of electrical and/or electronic components placed in said second housing chamber to at least one electrical component, especially a resistor and/or a coil and/or a capacitor, placed outside of the electronics housing; and/or
a section of the side wall of said housing basic body surrounding said first housing chamber is provided with at least one feed through opening for electrical connecting lines serving for the electrical, especially galvanic, connection of electrical components, especially connection terminals, placed in the first housing chamber to at least one electrical component, especially an external energy supply, placed outside of the electronics housing; and/or
said first housing chamber extends from the first side of said intermediate floor to an inner side of said housing lid facing said cavity of said housing basic body.

40. The electronics housing as claimed in claim 23, further comprising:
a partition sealing, especially dust or water spray tightly, wherein:
said first housing chamber on a side facing said housing lid and placed between said first housing chamber and said housing lid, especially a partition removable again via the open end of said housing basic body after removal of said housing lid from said housing basic body and/or a metal partition, for forming a third housing chamber extending between a first side of said partition facing said housing lid and an inner side of said housing lid facing the cavity of said housing basic body, especially a third housing chamber accommodating electrical assemblies satisfying a penetration protection type “Water Spray Protected (IP54)” and/or an ignition protection type “Intrinsic Safety (Ex-i)”.

41. The electronic device, comprising an electronics housing as claimed in claim 23, as well as a device electronics accommodated therein.

42. The electronic device as claimed in claim 23, further comprising:
a measuring transducer electrically coupled, especially galvanically connected, by means of a connecting line, to at least one electronic assembly placed in said second housing chamber; at least at times during operation, said measuring transducer provides, especially via said connecting line connected to the device electronics, a measurement signal corresponding to a physical and/or chemical measured variable of a medium, especially a medium in a pipeline and/or in a container.

43. The electronic device as claimed in claim 41, wherein:
at least one electrical component and/or an electronic assembly is placed on the second side of said intermediate floor, especially at least partially embedded in a potting compound provided on said side of said intermediate floor.

44. The use of an electronic device according to claim 41, for measuring a physical and/or chemical measured variable of a medium in a pipeline, especially one extending at least sectionally through an explosion endangered danger zone, and/or in a container, especially one placed within an explosion endangered danger zone.
